(19) United States
(12) Patent Application Publication
(10) Pub. No.: US 2026/0040444 A1
(43) Pub. Date: Feb. 5, 2026

(54) Fabric with Electrical Components

(71) Applicant: Apple Inc., Cupertino, CA (US)

(72) Inventors: Benjamin J Grena, San Francisco, CA (US); Kathryn P Crews, Menlo Park, CA (US); Tirshathah A Hunter, San Leandro, CA (US); Francois R Jacob, Sunnyvale, CA (US); Daniel A Podhajny, Morgan Hill, CA (US); Andrew L Rosenberg, Sunnyvale, CA (US); Jenna L Withrow, Campbell, CA (US)

(21) Appl. No.: 19/233,129

(22) Filed: Jun. 10, 2025

Related U.S. Application Data
(60) Provisional application No. 63/679,536, filed on Aug. 5, 2024.

(51) Int. Cl. H05K 1/03; H05K 1/02; H05K 1/18

(52) U.S. Cl. CPC H05K 1/038; H05K 1/0271; H05K 1/189

(57) ABSTRACT

Fabric may include conductive strands and electrical components. The fabric may include first and second fabric segments separated by a gap. An electrical component may be mounted in the gap. The first fabric segment may have a first conductive strand that terminates in the gap and electrically couples to the component. The second fabric segment may have a second conductive strand that terminates in the gap and electrically couples to the component. An electrical component may be mounted in a recess in fabric and may be attached to conductive strands that terminate in the recess. Polymer material may be overmolded onto the component and may attach the component to the surrounding fabric. The polymer material and the electrical component may have mating engagement features. Fabric edges may overlap one another at a joint and may be sandwiched between first and second portions of an electrical component.

This application claims the benefit of U.S. provisional patent application No. 63/679,536, filed Aug. 5, 2024, which is hereby incorporated by reference herein in its entirety.

### FIELD

This relates generally to items with fabric and, more particularly, to items with fabric and electrical components.

### BACKGROUND

It may be desirable to form bags, furniture, clothing, and other items from materials such as fabric. Fabric items generally do not include electrical components. It may be desirable, however, to incorporate electrical components into fabric to provide a user of a fabric item with enhanced functionality.

It can be challenging to incorporate electrical components into fabric. Fabric is flexible, so it can be difficult to mount structures to fabric. Electrical components must be coupled to signal paths (e.g., signal paths that carry data signals, power, etc.), but unless care is taken, signal paths may be damaged, or components may become dislodged as fabric is bent and stretched.

### SUMMARY

Fabric may include conductive strands and electrical components. The electrical components may be mounted to the fabric and electrically connected to the conductive strands after the fabric is formed.

The fabric may include first and second fabric segments separated by a gap. An electrical component may be mounted in the gap. The first fabric segment may have a first conductive strand that terminates in the gap and that is electrically coupled to the component, and the second fabric segment may have a second conductive strand that terminates in the gap and that is electrically coupled to the component. Polymer material may be overmolded onto the component and may attach the component to the surrounding fabric. The polymer material, the electrical component, and the fabric may have mating engagement features that help secure the component to the fabric.

In some arrangements, an electrical component may be mounted in a recess in the fabric. Conductive strands in the fabric may terminate in the recess and may be electrically coupled to the component.

In some arrangements, first and second fabric edges may overlap one another at a joint and may be sandwiched between first and second portions of an electrical component. The first and second fabric edges may be flat or may have interlocking wavy shapes. A pin or other connection between the first and second portions of the electrical component may pass through the first and second fabric edges.

### BRIEF DESCRIPTION OF THE DRAWINGS

FIG. 1 is a diagram of an illustrative item that may include fabric with electrical components in accordance with some embodiments.

FIG. 2 is a side view of an illustrative fabric that includes one or more conductive strands in accordance with some embodiments.

FIG. 3 is a side view an illustrative fabric that includes a conductive strand with one or more floats in accordance with some embodiments.

FIG. 4 is a side view of the fabric of FIG. 3 showing how an electrical component may be coupled to an exposed conductive strand in accordance with some embodiments.

FIG. 5 is a side view of the fabric of FIG. 4 showing how a cover layer may wrap around a fabric with an electrical component in accordance with some embodiments.

FIG. 6 is a perspective view of an illustrative fabric having embedded conductive strands in accordance with some embodiments.

FIG. 7 is a perspective view of an illustrative rolled up fabric with embedded conductive strands in accordance with some embodiments.

FIG. 8 is a perspective view of an illustrative tube of fabric with embedded conductive strands in accordance with some embodiments.

FIG. 9 is a perspective view of an illustrative fabric having a region with locally reduced thickness and exposed loops of conductive strands in accordance with some embodiments.

FIG. 10 is a side view of an illustrative item having an electrical component mounted in a gap between first and second fabric segments in accordance with some embodiments.

FIG. 11 is a side view of an illustrative item having an electrical component mounted to an outer surface of fabric in accordance with some embodiments.

FIG. 12 is a side view of an illustrative item having an electrical component with a first portion mounted to a first fabric surface and a second portion mounted to a second opposing fabric surface in accordance with some embodiments.

FIG. 13 is a side view of an illustrative item having an electrical component mounted in a fabric recess and secured to the fabric using molded polymer in accordance with some embodiments.

FIG. 14 is a side view of an illustrative item having an electrical component mounted in a fabric recess and flush with an outer surface of the fabric in accordance with some embodiments.

FIG. 15 is a side view of an illustrative item having an electrical component coupled to a conductive strand in fabric and secured within the fabric using molded polymer and one or more non-woven composite materials in accordance with some embodiments.

FIG. 16 is a side view of an illustrative item having an electrical component coupled to a conductive strand in fabric and secured within the fabric using molded polymer having one or more engagement features in accordance with some embodiments.

FIG. 17 is a top view of an illustrative item having an electrical component mounted in a gap between first and second fabric segments in accordance with some embodiments.

FIG. 18 is a top view of an illustrative item having multiple electrical components each mounted in a respective gap between first and second fabric segments in accordance with some embodiments.

FIG. 19 is a perspective view of an illustrative item having an electrical component received within a fabric recess in accordance with some embodiments.

FIG. 20 is a perspective view of an illustrative item having an electrical component mounted in a gap between first and second fabric segments in accordance with some embodiments.

FIG. 21 is a perspective view of an illustrative item having an electrical component coupled to fabric that wraps around a core in accordance with some embodiments.

FIG. 22 is a perspective view of illustrative item having an electrical component coupled to surrounding fabric using molded polymer in accordance with some embodiments.

FIG. 23 is a perspective view of an illustrative item having electrical components received within fabric openings in accordance with some embodiments.

FIGS. 24, 25, and 26 are side views of illustrative items with electrical components mounted between fabric segments having different types of overlap joints in accordance with some embodiments.

### DETAILED DESCRIPTION

Electronic devices, enclosures, and other items may be formed from fabric such as woven fabric, knit fabric, braided fabric, and/or other suitable fabric. The fabric may include strands of insulating and conductive material that form circuitry. Conductive strands may form signal paths through the fabric and may be coupled to electrical components such as light-emitting diodes and other light-emitting devices, integrated circuits, sensors, haptic output devices, and other circuitry.

Interlacing equipment (sometimes referred to as intertwining equipment) may include weaving equipment, knitting equipment, braiding equipment, or any other suitable equipment used for crossing, looping, overlapping, or otherwise coupling strands of material together to form a network of strands (e.g., fabric). The strands of material may include conductive strands for conveying electrical signals between electrical components. One or more electrical components may be coupled to conductive strands in the fabric. The electrical components may be incorporated into the fabric during interlacing operations (e.g., while the fabric is being formed) and/or may be incorporated into the fabric after the fabric is formed. An electrical component may, for example, be mounted in a gap between first and second fabric segments, may be mounted in a recess or opening in the fabric, may be mounted to an outer surface of the fabric, and/or may be mounted in other locations of the fabric. Molded polymer, adhesive, stitching, mating engagement structures, and/or other attachment structure may be used to help secure the electrical component to the surrounding fabric.

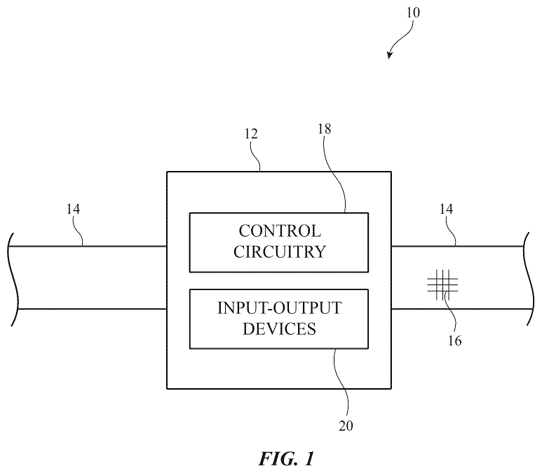

An illustrative item that may include fabric with one or more electrical components is shown in FIG. 1. Item 10 of FIG. 1 (sometimes referred to as an electronic device, a fabric-based item, electronic equipment, etc.) may be an electronic device or an accessory for an electronic device such as an ear bud, a voice-controlled electronic device (sometimes referred to as a digital assistant or voice-controlled speaker), a laptop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which fabric-based item 10 is mounted in a kiosk, in an automobile, airplane, or other vehicle, other electronic equipment, or equipment that implements the functionality of two or more of these devices. If desired, item 10 may be a removable external case for electronic equipment, may be a strap, may be a wrist band or head band, may be a removable cover for a device, may be a case or bag that has straps or that has other structures to receive and carry electronic equipment and other items, may be a necklace or arm band, may be a wallet, sleeve, pocket, or other structure into which electronic equipment or other items may be inserted, may be part of a chair, sofa, or other seating (e.g., cushions or other seating structures), may be part of an item of clothing or other wearable item (e.g., a hat, belt, wrist band, headband, shirt, pants, shoes, etc.), or may be any other suitable fabric-based item. In the illustrative configuration of FIG. 1, item 10 is device that wraps around part of a user's body. For example, item 10 may be a head-mounted device having fabric that wraps around a user's head, may be a wristwatch device having fabric that wraps around a user's wrist, and/or may be any other suitable fabric-based item. Other types of devices may incorporate fabric, if desired.

As shown in FIG. 1, item 10 may include a housing such as housing 12. Housing 12 may have a wristband shape, a headband shape, an ear bud shape, a headphones shape, a cylindrical shape, a spherical shape, or any other suitable shape (e.g., a pyramidal shape, a conical shape, a box shape such as a rectangular box shape, etc.). Housing 12 may include support structures formed from metal, polymer, ceramic, glass, wood, other materials, and/or combinations of these materials.

Item 10 may include fabric 14. Fabric 14 may form all or part of a housing wall or other layer in an electronic device, may form a band or strap for attaching item 10 to a body of a user, may form internal structures in an electronic device, or may form other fabric-based structures. Item 10 may be soft (e.g., item 10 may have a fabric surface that yields to a light touch), may have a rigid feel (e.g., the surface of item 10 may be formed from a stiff fabric), may be coarse, may be smooth, may have ribs or other patterned textures, and/or may be formed as part of a device that has portions formed from non-fabric structures of plastic, metal, glass, crystalline materials, ceramics, or other materials. For example, some or all of the upper surface of housing 12, the sidewall surfaces of housing 12, surfaces associated with lower portions of housing 12, and/or other portions of item 10 may be covered with fabric 14. In some configurations, fabric 14 may serve as a cosmetic cover for item 10 that is permeable to sound.

Fabric 14 may include interlaced strands of material such as strands 16. As used herein, “interlaced” strands of material and “intertwined” strands of material may both refer to strands of material that are crossed with one another, looped with one another, overlapping one another, or otherwise coupled together (e.g., as part of a network of strands that make up a fabric). Fabric 14 may be woven fabric, knit fabric, braided fabric, and/or any other suitable type of fabric. Strands 16 may be single-filament strands (sometimes referred to as fibers or monofilaments) or may be strands of material formed by intertwining multiple monofilaments of material together (sometimes referred to as yarns).

Strands 16 may be formed from polymer, metal, glass, graphite, ceramic, natural materials such as cotton or bamboo, other organic and/or inorganic materials, and combinations of these materials. Conductive coatings such as metal coatings may be formed on non-conductive material. For example, plastic strands in fabric 14 may be coated with metal to make them conductive. Reflective coatings such as metal coatings may be applied to make strands reflective. Strands may be formed from bare metal wires or metal wire intertwined with insulating monofilaments (as examples). Bare metal strands and strands of polymer covered with conductive coatings may be provided with insulating polymer jackets.

Strands 16 in fabric 14 may be conductive along their entire lengths or may have conductive portions. Strands may have metal portions that are selectively exposed by locally removing insulation (e.g., to form connections with other conductive strand portions and/or to form connections with electrical components). Strands 16 may also be formed by selectively adding a conductive layer to a portion of a non-conductive strand. Threads and other multifilament yarns that have been formed from interlaced filaments may contain mixtures of conductive strands and insulating strands (e.g., metal strands or metal coated strands with or without exterior insulating layers may be used in combination with solid plastic strands or natural strands that are insulating). In some arrangements, which may sometimes be described herein as an example, fabric 14 may be a woven fabric and the strands that make up fabric 14 may include warp strands and weft strands.

Conductive strands and insulating strands may be woven, knit, or otherwise interlaced to form conductive paths. The conductive paths may be used in forming signal paths (e.g., signal buses, power lines for carrying power, etc.), may be used in forming part of a capacitive touch sensor electrode, a resistive touch sensor electrode, or other input-output device, or may be used in forming other patterned conductive structures. Conductive structures in fabric 14 may be used in carrying electrical current such as power, digital signals, analog signals, sensor signals, control signals, data, input signals, output signals, or other suitable electrical signals.

To enhance mechanical robustness and electrical conductivity at strand-to-strand connections and/or strand-to-component connections, additional structures and materials (e.g., solder, crimped metal connections, welds, conductive adhesive such as anisotropic conductive film and other conductive adhesive, non-conductive adhesive, fasteners, etc.) may be used in fabric 14. Strand-to-strand connections may be formed where strands cross each other perpendicularly or at other strand intersections where connections are desired. Insulating material can be interposed between intersecting conductive yarns at locations in which it is not desired to form a strand-to-strand connection. The insulating material may be plastic or other dielectric, may include an insulating strand or a conductive strand with an insulating coating or insulated conductive monofilaments, etc. Solder connections may be formed between conductive strands and/or between conductive strands and electrical components by melting solder so that the solder flows over conductive strands. The solder may be melted using an inductive soldering head to heat the solder, using hot air to heat the solder, using a reflow oven to heat the solder, using a laser or hot bar to heat the solder, or using other soldering equipment. In some arrangements, outer dielectric coating layers (e.g., outer polymer layers) may be melted away in the presence of molten solder, thereby allowing underlying metal yarns to be soldered together. In other arrangements, outer dielectric coating layers may be removed prior to soldering (e.g., using laser ablation equipment or other coating removal equipment).

Items such as item 10 may, if desired, include control circuitry 18. Control circuitry 18 may include microprocessors, microcontrollers, application-specific integrated-circuits, digital signal processors, baseband processors, and/or other controllers and may include storage such as random-access memory, read-only memory, solid state drives, and/or other storage and processing circuitry.

Control circuitry 18 may gather information from sensors and other circuitry in input-output devices 20 and may use input-output devices 20 to supply output. Input-output devices 20 may, for example, include audio devices such as microphones and speakers. Microphones can gather audio input (e.g., sound that passes through fabric 14). Speakers can produce audio output (e.g., sound that passes through fabric 14). Sensors in input-output devices 20 may include touch sensors, force sensors, capacitive sensors, optical sensors, proximity sensors, strain gauges, temperature sensors, moisture sensors, gas sensors pressure sensors, magnetic sensors, position and orientation sensors (e.g., accelerometers, gyroscopes, and/or compasses), and/or other sensors. Light-emitting diodes, displays, and other visual output devices may be used to supply visual output to a user. Buttons, joysticks, haptic output components, and/or other input-output components may be provided in input-output devices 20 to gather input from a user and to provide a user with output. Wireless circuitry in circuitry 18 (e.g., wireless local area network circuitry, cellular telephone circuitry, etc.) may be used to support wireless communications with external equipment.

Integrated circuits and other electrical components forming circuitry 18 and/or input-output devices 20 may be mounted in housing 12. Fabric 14 may form a fabric strap or band that attaches device 10 to a user's wrist, head, or other body part. In some arrangements, fabric 14 may cover the exterior of housing 12 (e.g., to hide electrical components in housing 12 from view). Fabric 14 may also be used in forming structural portions of housing 12 and/or other portions of item 10, may be used in forming covers, wearable items, and/or other structures for item 10.

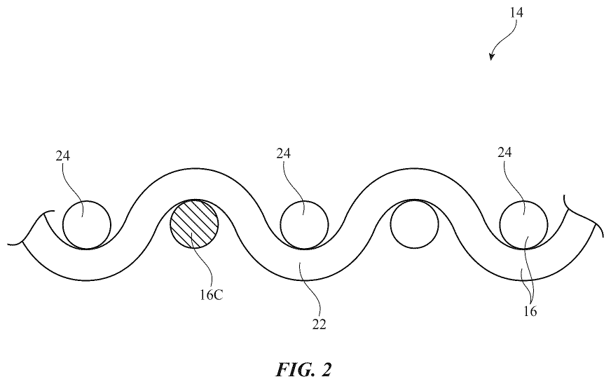

A cross-sectional side view of illustrative woven fabric 14 is shown in FIG. 2. As shown in FIG. 2, fabric 14 may include strands 16. Strands 16 may include warp strands 22 and weft strands 24. If desired, additional strands that are neither warp nor weft strands may be incorporated into fabric 14. The example of FIG. 2 is merely illustrative. In the illustrative configuration of FIG. 2, fabric 14 has a single layer of woven strands 16. Multi-layer fabric constructions may be used for fabric 14 if desired.

As shown in FIG. 2, strands 16 of fabric 14 may include one or more conductive strands such as conductive strand 16C. Conductive strands 16C (sometimes referred to as “wires”) may be configured to carry electrical signals (e.g., power, digital signals, analog signals, sensor signals, control signals, data, input signals, output signals, or other suitable electrical current) to and/or from electrical components. Strands 16C may be warp strands (e.g., warp strands 22), weft strands (e.g., weft strands 24), or other suitable strands 16 in fabric 14 (e.g., knitted strands, braided strands, inlaid or inserted strands, etc.).

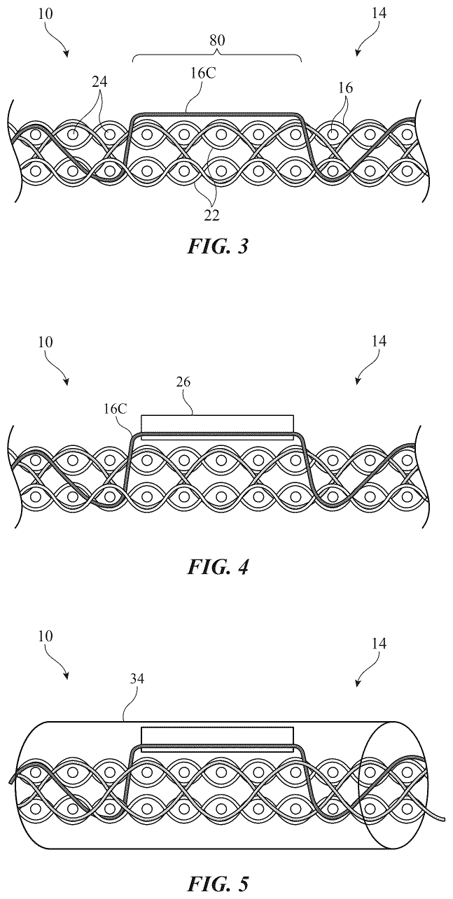

FIGS. 3, 4, and 5 are side views of fabric 14 showing how one or more electrical components may be incorporated into fabric 14. As shown in FIG. 3, fabric 14 may include one or more layers of fabric formed from interlaced weft strands 24 and warp strands 22. One or more conductive stands 16C may be incorporated into fabric 14. In the example of FIG. 3, conductive strand 16C forms a warp strand 22. This is merely illustrative. If desired, conductive strands 16C may form weft strands 24 in fabric 14 instead of or in addition to forming warp strands 22 in fabric 14. Arrangements in which conductive strand 16C is neither a weft nor a warp strand may also be used.

Conductive strand 16C may have one or more exposed conductive segments such as exposed conductive segments 80 for forming electrical connections with electrical components, for forming electrical connections with other conductive strands 16C, for forming conductive electrodes, and/or for forming other circuitry within item 10. Conductive segment 80 may be exposed on an outer surface of fabric 14, may be exposed between separate segments of fabric 14, may be exposed at one or more ends of fabric 14, may be exposed in one or more locally thinned regions of fabric 14, and/or may be exposed elsewhere in fabric 14. In the example of FIG. 3, conductive strand 16C forms a float that passes over multiple consecutive weft strands 24. The float formed by conductive segment 80 of strand 16C may be exposed on an outer surface of fabric 14.

FIG. 4 shows how an electrical component such as electrical component 26 may be mounted to exposed conductive segment 80 of strand 16C. Electrical components in item 10 such as illustrative electrical component 26 may include discrete electrical components such as resistors, capacitors, and inductors, may include connectors, may include batteries, may include input-output devices such as switches, buttons, light-emitting components such as light-emitting diodes, audio components such as microphones and speakers, vibrators (e.g., piezoelectric actuators that can vibrate), solenoids, electromechanical actuators, motors, and other electromechanical devices, microelectromechanical systems (MEMs) devices, pressure sensors, light detectors, proximity sensors (light-based proximity sensors, capacitive proximity sensors, etc.), force sensors (e.g., piezoelectric force sensors), strain gauges, moisture sensors, temperature sensors, accelerometers, gyroscopes, compasses, magnetic sensors (e.g., Hall effect sensors and magnetoresistance sensors such as giant magnetoresistance sensors), touch sensors, and other sensors, components that form displays, touch sensors arrays (e.g., arrays of capacitive touch sensor electrodes to form a touch sensor that detects touch events in two dimensions), and other input-output devices, electrical components that form control circuitry such as non-volatile and volatile memory, microprocessors, application-specific integrated circuits, system-on-chip devices, baseband processors, wired and wireless communications circuitry, and other integrated circuits.

Electrical components such as component 26 may be bare semiconductor dies (e.g., laser dies, light-emitting diode dies, integrated circuits, etc.) or packaged components (e.g. semiconductor dies or other devices packaged within plastic packages, ceramic packages, or other packaging structures).

If desired, component 26 may be coupled to only a single conductive strand 16C, may be coupled to two conductive strands 16C, or may be coupled to three or more conductive strands 16C.

To increase the robustness of the connection between strands 16C and component 26, component 26 may have one or more recesses for receiving strands 16C (if desired). For example, strands 16C may be threaded through a portion of component 26 to help secure component 26 to fabric 12. Strands 16C may be threaded through recesses, openings, trenches, grooves, holes, and/or other engagement features of component 26.

FIG. 5 shows how a cover layer such as cover layer 34 may optionally be formed over fabric 14 and electrical component 26. Cover layer 34 may be formed from fabric (e.g., woven fabric, knit fabric, braided fabric, spacer fabric, printed fabric, etc.), polymer, elastomer, silicone, leather, and/or any other suitable material. Cover layer 34 may form a sleeve (e.g., a tube, sheath, etc.) that wraps entirely around fabric 14 and/or that wraps around certain segments of fabric 14. Cover layer 34 may have a cylindrical shape, may have a planar shape (e.g., may be formed from one or more planar sheets of material that sandwich fabric 14), and/or may have any other suitable shape. Cover layer 34 may overlap electrical component 26 and may help hide electrical component 26 from view, if desired.

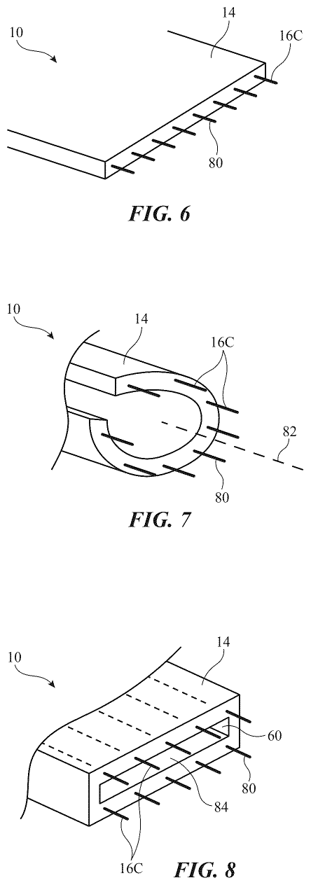

FIGS. 6, 7, and 8 show illustrative configurations for fabric 14 of FIGS. 3, 4, and 5. In the example of FIG. 6, fabric 14 is formed from a single layer (e.g., a sheet) of fabric. Fabric 14 may include non-conductive strands as well as one or more conductive strands 16C. As shown in FIG. 6, fabric 14 forms a strip of webbing and conductive strands 16C extend along the length of the webbing (e.g., in the warp direction, if desired). Conductive strands 16C may include exposed conductive segments 80 that protrude from fabric 14 (e.g., that protrude out from the end of a fabric segment) and/or that are otherwise exposed on fabric 14. Electrical components such as component 26 of FIGS. 4 and 5 may be electrically coupled to exposed conductive segments 80 of strands 16C in fabric 14. If desired, fabric 14 of FIG. 6 may be covered and/or wrapped in one or more cover layers such as cover layer 34 of FIG. 5.

In the example of FIG. 7, fabric 14 is formed from a single layer (e.g., a sheet) of fabric that has been rolled up. In particular, fabric 14 may be rolled up around a longitudinal axis such as axis 82. Fabric 14 may include non-conductive strands as well as one or more conductive strands 16C. As shown in FIG. 7, fabric 14 forms a rounded tube of webbing and conductive strands 16C extend along the length of the webbing (e.g., parallel to axis 82, if desired). Conductive strands 16C may include exposed conductive segments 80 that protrude from fabric 14 (e.g., that protrude out from the end of a fabric segment) and/or that are otherwise exposed on fabric 14. Electrical components such as component 26 of FIGS. 4 and 5 may be electrically coupled to exposed conductive segments 80 of strands 16C in fabric 14. If desired, fabric 14 of FIG. 7 may be covered and/or wrapped in one or more cover layers such as cover layer 34 of FIG. 5.

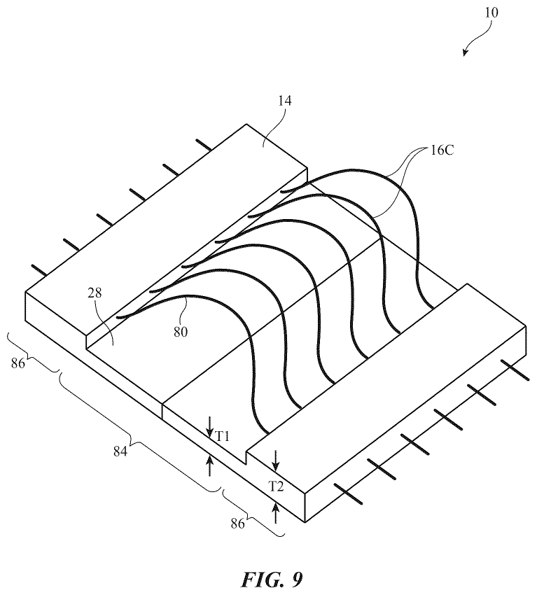

In the example of FIG. 8, fabric 14 is formed from a tube of fabric that has a central opening such as opening 84. Fabric 14 may include non-conductive strands as well as one or more conductive strands 16C. As shown in FIG. 8, fabric 14 forms rectangular tube of webbing and conductive strands 16C extend along the length of the tube (e.g., in the warp direction, if desired). Conductive strands 16C may include exposed conductive segments 80 that protrude from fabric 14 (e.g., that protrude out from the end of a fabric segment) and/or that are otherwise exposed on fabric 14. Electrical components such as component 26 of FIGS. 4 and 5 may be electrically coupled to exposed conductive segments 80 of strands 16C in fabric 14. If desired, fabric 14 of FIG. 8 may be covered and/or wrapped in one or more cover layers such as cover layer 34 of FIG. 5.

FIG. 9 is a perspective view of item 10 showing how conductive strands 16C may form one or more loops on the surface of fabric 14 for forming electrical connections with components such as component 26. As shown in FIG. 9, fabric 14 may include regions of different thickness such as region 84 with thickness Tl and region 86 with thickness T2. Thickness T1 in region 84 may be less than thickness T2 in region 86. This forms a recess in fabric 14 such as recess 28. Recess 28 may be formed during interlacing operations (e.g., recess 28 may be formed during weaving, knitting, braiding, etc.), or recess 28 may be produced after fabric 14 is formed (e.g., by debossing, stamping, cutting, or otherwise processing fabric 14 after fabric 14 is formed). Conductive strands 16C may include exposed conductive segments 80 in recess 28. To provide sufficient slack for forming electrical connections with component 26, conductive strands 16C may have a loop shape or may otherwise be provided with a non-straight segment in recess 28. Electrical components 26 of FIGS. 4 and 5 may be electrically coupled to exposed conductive segments 80 of strands 16C in fabric 14. If desired, fabric 14 of FIG. 9 may be covered and/or wrapped in one or more cover layers such as cover layer 34 of FIG. 5.

If desired, conductive segments 80 of fabric 14 may be exposed by applying heat to fabric 14 to shrink fabric 14 (e.g., to shrink fabric 14 along its length). Because conductive strands 16C remain the same length while the rest of fabric 14 shrinks, heat shrinking fabric 14 may expose conductive segments 80 of strands 16C (e.g., at one or more ends of fabric 14).

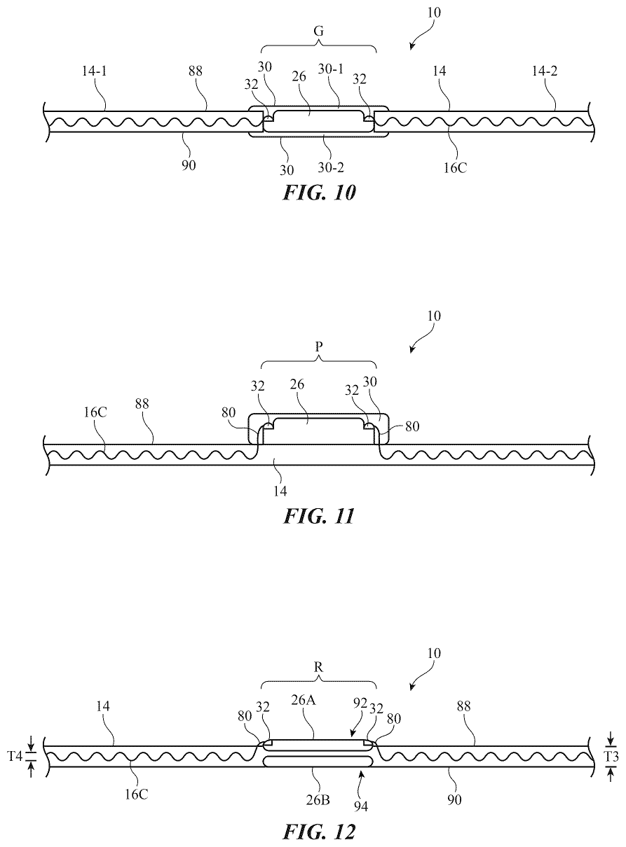

FIG. 10 is a side view of item 10 showing how component 26 may be attached between first and second segments of fabric 14. Fabric 14 may include one or more separate segments such as fabric segment 14-1 and fabric segment 14-2. Fabric segments 14-1 and 14-2 may be separated by a gap such as gap G. Gap G may be formed by cutting fabric 14 to form segments 14-1 and 14-2, or gap G may be formed between two separately formed fabric segments 14-1 and 14-2. Conductive strands 16C may span continuously across gap G (e.g., one or more of conductive strands 16C may be interlaced with both fabric segments 14-1 and 14-2 and may span across gap G), or conductive strands 16C may have ends that terminate in gap G. Component 26 may include one or more electrical contacts such as contacts 32 (e.g., terminals, leads, solder pads, solder bumps, contact pads, etc.) electrically coupled to exposed conductive segments 80 of conductive strands 16C in gap G. Because component 26 is mounted in gap G, component 26 may be flush with outer surfaces of fabric 14 such as outer surface 88 and opposing outer surface 90, if desired.

To help secure component 26 to fabric segments 14-1 and 14-2, one or more portions of component 26 may be covered by an encapsulant such as molded polymer material 30. Polymer 30 may be molded over opposing surfaces of component 26 and over opposing surfaces of fabric segments 14-1 and 14-2. In some arrangements, polymer material 30 may be a thermosetting or thermoplastic polymer that is initially soft and pliable (e.g., when melted) and that hardens as it cools and solidifies. Polymer material 30 may capture the ends of strands 16, may fill gaps between strands 16, and/or may form other mechanical and/or chemical bonds with strands 16 (including conductive strand 16C) of fabric segments 14-1 and 14-2 to help secure component 26 to fabric segments 14-1 and 14-2. In the example of FIG. 10, component 26 is interposed between first and second portions of polymer material 30 such as first portion 30-1 and second portion 30-2. First portion 30-1 may span across gap G and may be located at least partially on outer surface 88 of fabric 14, while second portion 30-2 may span across gap G and may be located at least partially on outer surface 90 of fabric 14. If desired, fabric 14 may be covered and/or wrapped in one or more cover layers such as cover layer 34 of FIG. 5.

In the example of FIG. 11, component 26 is mounted to an outer surface of fabric 14 such as region P of outer surface 88. Conductive strands 16C may include exposed conductive segments 80 that protrude out from fabric 14 (e.g., from outer surface 88) to form electrical connections with component 26 in region P. If desired, conductive strands 16C may span continuously across region P of surface 88, or conductive strands 16C may have ends that terminate in region P. The exposed conductive segments 80 of conductive strands 16C in region P may be electrically coupled to contacts 32 on component 26.

To help secure component 26 to fabric 14, one or more portions of component 26 may be covered by an encapsulant such as molded polymer material 30. Polymer 30 may be molded over component 26 and fabric 14 (e.g., surface 88 of fabric 14). Polymer material 30 may capture the ends of strands 16 (e.g., conductive strands 16C), may fill gaps between strands 16, and/or may form other mechanical and/or chemical bonds with strands 16 of fabric 14. If desired, fabric 14 may be covered and/or wrapped in one or more cover layers such as cover layer 34 of FIG. 5.

In the example of FIG. 12, fabric 14 has one or more regions R with locally reduced thickness for accommodating electrical components such as component 26. In particular, fabric 14 may have a first thickness T3 in regions without components 26 and may have a second, reduced thickness T4 in regions R where components 26 are located. Thickness T4 may be less than thickness T3 such that one or more recesses are formed in fabric 14 such as recess 92 in surface 88 and recess 94 in surface 90. Recesses 92 and 94 may overlap one another or may be non-overlapping with one another. Recesses 92 and 94 may be formed during interlacing operations (e.g., recesses 92 and 94 may be formed during weaving, knitting, braiding, etc.), or recesses 92 and 94 may be produced after fabric 14 is formed (e.g., by debossing, stamping, cutting, or otherwise processing fabric 14 after fabric 14 is formed). Recess 92 may receive electrical component 26A and recess 94 may receive electrical component 26B. Electrical components 26A and 26B may be two different electrical components, or electrical components 26A and 26B may be first and second portions of the same electrical component. If desired, electrical connections and/or mechanical connections between components 26A and 26B may pass through fabric 14 in region R, or components 26A and 26B may not be connected to one another.

Conductive strands 16C may include exposed conductive segments 80 that protrude out from fabric 14 (e.g., from outer surface 88, from outer surface 90, from recess 92, and/or from recess 94) to form electrical connections with component 26 in region R. If desired, conductive strands 16C may span continuously across region R (e.g., continuously across recess 92 and/or recess 94), or conductive strands 16C may have ends that terminate in region R (e.g., ends that terminate in recess 92 and/or in recess 94). The exposed conductive segments 80 of conductive strands 16C in region R may be electrically coupled to contacts 32 on component 26.

If desired, one or more portions of component 26 may be covered by an encapsulant (e.g., molded polymer material 30 of FIGS. 10 and 11) to help secure component 26 to fabric 14. If desired, fabric 14 may be covered and/or wrapped in one or more cover layers such as cover layer 34 of FIG. 5.

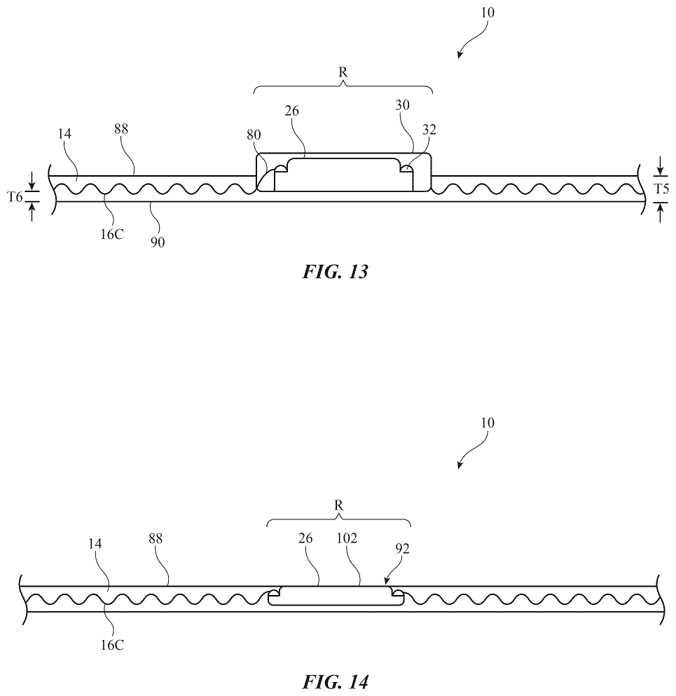

The example of FIG. 12 in which regions R of locally reduced thickness include a recess in surface 88 and in surface 90 is merely illustrative. If desired, regions R of locally reduced thickness may include only a single recess (e.g., in surface 88 or in surface 90). This type of arrangement is shown in FIG. 13. As shown in FIG. 13, region R of locally reduced thickness may include recess 92 in surface 88, without any recess in surface 90. Fabric 14 may have a first thickness T5 in regions without components 26 and may have a second, reduced thickness T6 in regions R where components 26 are located. Thickness T6 may be less than thickness T5 such that recess 92 is formed in surface 88.

Conductive strands 16C may include exposed conductive segments 80 that protrude out from fabric 14 (e.g., from outer surface 88 and/or from recess 92) to form electrical connections with component 26 in region R. If desired, conductive strands 16C may span continuously across region R (e.g., continuously across recess 92), or conductive strands 16C may have ends that terminate in region R (e.g., ends that terminate in recess 92). The exposed conductive segments 80 of conductive strands 16C in region R may be electrically coupled to contacts 32 on component 26.

If desired, one or more portions of component 26 may be covered by an encapsulant such as molded polymer material 30 to help secure component 26 to fabric 14. Polymer 30 may be molded over component 26 and fabric 14 (e.g., surface 88 of fabric 14). Polymer material 30 may capture the ends of strands 16 (e.g., conductive strands 16C), may fill gaps between strands 16, and/or may form other mechanical and/or chemical bonds with strands 16 of fabric 14. If desired, fabric 14 may be covered and/or wrapped in one or more cover layers such as cover layer 34 of FIG. 5.

The example of FIG. 13 in which component 26 protrudes above outer surface 88 of fabric 14 is merely illustrative. If desired, component 26 may be mounted in one or more recesses in fabric 14 such that component 26 is flush with outer surface 88 of fabric 14. This example is illustrated in FIG. 14. As shown in FIG. 14, component 26 may be mounted in recess 92 and may have an outer surface 102 that is flush with (or recessed with respect to) outer surface 88 of fabric 14. If desired, a molded polymer material (e.g., polymer 30) may be molded around the edges of component 26 and may help secure component 26 to fabric 14. If desired, fabric 14 may be covered and/or wrapped in one or more cover layers such as cover layer 34 of FIG. 5.

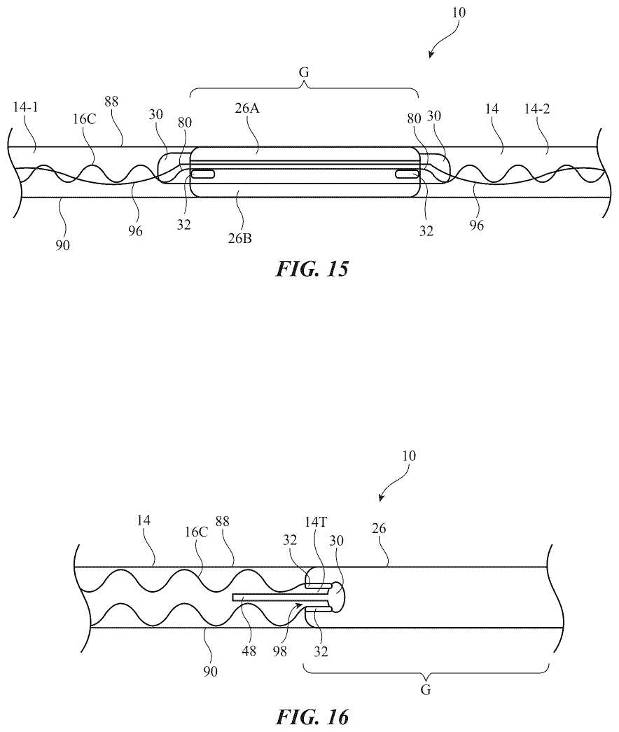

In the example of FIG. 15, component 26 is mounted in gap G between first and second fabric segments 14-1 and 14-2, similar to the example of FIG. 10. To help secure component 26 to fabric segments 14-1 and 14-2, polymer 30 may be molded onto component 26 and fabric segments 14-1 and 14-2. Rather than forming an exposed outer layer on fabric 14, polymer 30 forms an internal attachment structure between outer surfaces 88 and 90 of fabric 14. Polymer 30 may be a bead of polymer that runs around some or all of the periphery of component 26 and that captures the ends of strands 16 in fabric 14 to help secure component 26 to fabric segments 14-1 and 14-2.

If desired, one or more additional materials such as material 96 may be incorporated into fabric segments 14-1 and 14-2 and may span across gap G to help secure component 26 to fabric 14. In particular, material 96 may be a strand or strip of material (e.g., a non-woven composite material with high tensile strength or any other suitable material) that is integrated (e.g., woven, knit, braided, inserted, etc.) with fabric segments 14-1 and 14-2 and that is exposed in gap G. Component 26 may have a first portion 26A and a second portion 26B that are mounted to the exposed portion of material 96 in gap G. In particular, component portions 26A and 26B may clamp onto opposing sides of material 96 (e.g., such that material 96 is interposed between component portions 26A and 26B) to thereby secure component 26 in gap G. If desired, fabric 14 may be covered and/or wrapped in one or more cover layers such as cover layer 34 of FIG. 5.

FIG. 16 shows how component 26, polymer 30, and/or fabric 14 may include one or more mating engagement features (e.g., protrusions, recesses, interlocking elements, and/or other mating engagement features) for securing component 26 to fabric 14. For example, fabric 14 may include one or more protrusions such as protruding edge portion 14T that is received with a recess in component 26 such as recess 98. Polymer 30 may be molded to include one or more protrusions such as protrusion 48 that protrudes into fabric 14 (e.g., between outer surfaces 88 and 90). Protrusion 48 may extend around some or all of the periphery of component 26 and may capture the ends of strands 16 in fabric 14 to help secure component 26 to fabric segments 14. If desired, fabric 14 may be covered and/or wrapped in one or more cover layers such as cover layer 34 of FIG. 5.

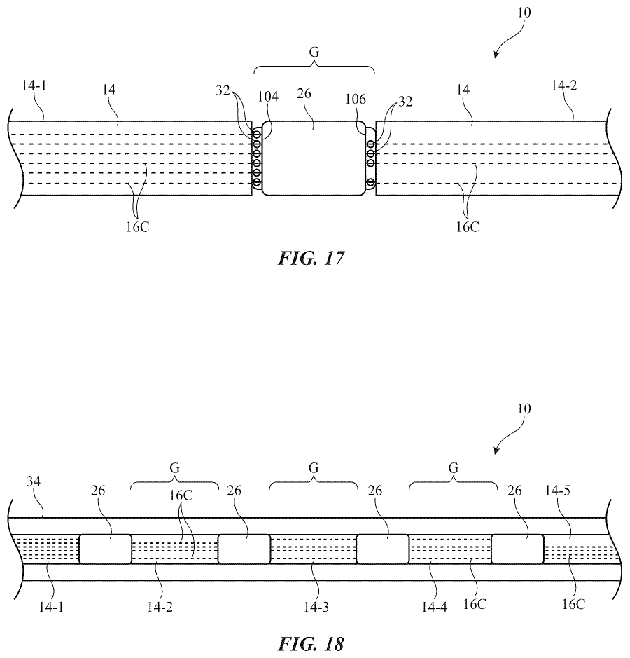

FIG. 17 is a top view of item 10 showing how mounting component 26 in gap G between fabric segments 14-1 and 14-2 may allow for some conductive strands 16C to only span across certain portions along the length of fabric 14. Because fabric segments 14-1 and 14-2 terminate at gap G, conductive strands 16C can also terminate at gap G when desired. This allows for different numbers of conductive strands 16C to be coupled to opposing sides of component 26, if desired. For example, component 26 may have first and second opposing edges such as edge 104 and edge 106. Edge 104 may have a first number of contacts 32 and edge 106 may have a second number of contacts 32 that is less than the first number of contacts 32. With this type of arrangement, fabric segment 14-1 may have a first number of conductive strands 16C that matches the first number of contacts 32 on edge 104, and fabric segment 14-2 may have a second number of conductive strands 16C that matches the second number of contacts on edge 106. If desired, fabric 14 may be covered and/or wrapped in one or more cover layers such as cover layer 34 of FIG. 5.

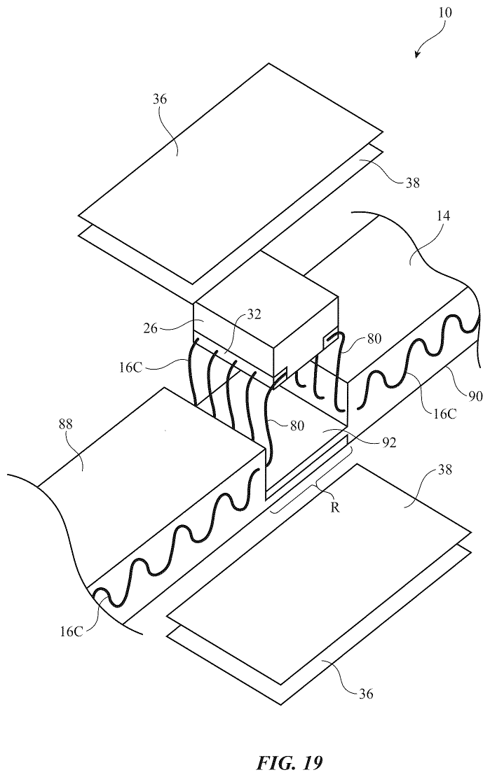

FIG. 18 is a top view of item 10 in which multiple gaps G are formed along the length of fabric 14 for receiving respective electrical components 26. In particular, fabric 14 may include multiple separate fabric segments such as fabric segments 14-1, 14-2, 14-3, 14-4, and 14-5, separated from one another by respective gaps G where the ends of those fabric segments terminate. If desired, conductive strands 16C may also terminate at respective gaps G, or some conductive strands 16C may span across one or more gaps G. If desired, different fabric segments may include different numbers of conductive strands (as discussed in connection with FIG. 17) to connect to different numbers of contacts 32 on opposing sides of component 26).

As shown in FIG. 18, a cover layer such as cover 34 may be wrapped around fabric 14. Cover layer 34 form a continuous tube around fabric 14, or cover layer 34 may have one or more separate portions such as upper and lower layers that sandwich fabric 14.

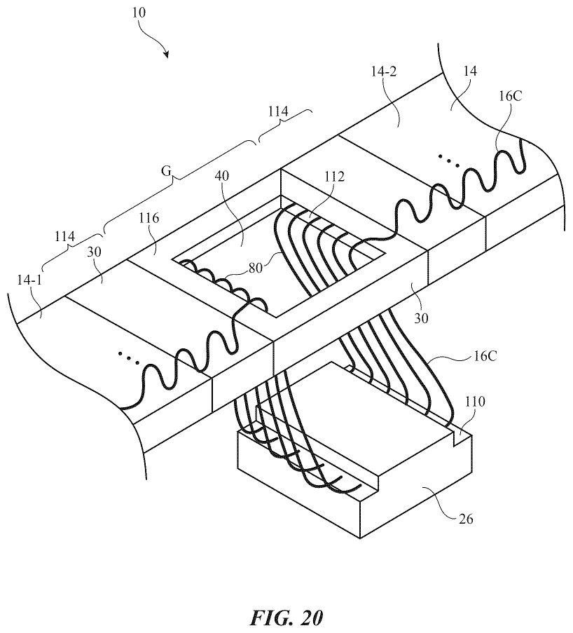

FIG. 19 is an exploded perspective view of item 10 showing another illustrative example in which component 26 is mounted in a recess such as recess 92 in reduced thickness region R of fabric 14 (e.g., similar to the examples of FIGS. 12, 13, and 14). Conductive strands 16C may include exposed conductive segments 80 that protrude out from fabric 14 (e.g., from recess 92 in the example of FIG. 19). The exposed conductive segments 80 of strands 16C may have ends that terminate in recess 92 of region R and that are electrically coupled to contacts 32 on component 26.

If desired, one or more strain relief layers such as strain relief layers 36 and 38 may be formed on opposing sides of component 26 and/or fabric 14. Strain relief layers 36 and 38 may include one or more stiffening layers, rigid polymer layers, adhesive layers, molded layers, and/or any other suitable layer for providing mechanical strength across region R and/or for adjusting the location of a neutral plane in fabric 14. If desired, fabric 14 may be covered and/or wrapped in one or more cover layers such as cover layer 34 of FIG. 5.

FIG. 20 is a perspective view of item 10 showing another illustrative example in which component 26 is mounted in a gap such as gap G in fabric 14 (e.g., similar to the examples of FIGS. 10 and 15-18). Conductive strands 16C may include exposed conductive segments 80 that protrude out from fabric 14 and that terminate in gap G to form electrical connections with component 26.

As shown in FIG. 20, polymer 30 may have a first portion such as portion 114 that captures the ends of fabric segments 14-1 and 14-2 and a second portion such as portion 116 that mates with electrical component 26. Polymer 30 may have an opening such as opening 40 that receives component 26. If desired, polymer 30 and component 26 may have mating engagement features to help secure component 26 to fabric 14. For example, component 26 may have one or more recesses such as recess 110 (e.g., a ledge along the edge of component 26) that receives a protruding portion of polymer 30 such as protruding edge 112. If desired, fabric 14 may be covered and/or wrapped in one or more cover layers such as cover layer 34 of FIG. 5.

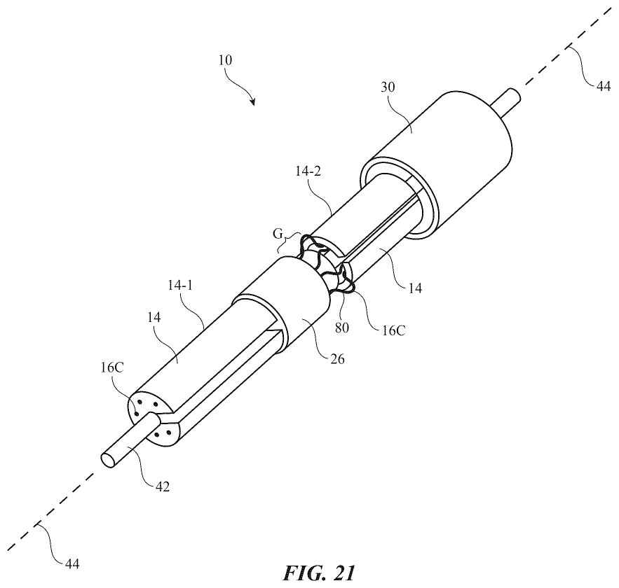

FIG. 21 is a cutaway view of item 10 showing how fabric 14, component 26, and polymer 30 may be wrapped around a central core such as core 42. Core 42 may be a metal rod, a flexible cable, a strand of fabric, a rigid member, and/or any other suitable elongated core extending along a longitudinal axis such as axis 44. As in the examples of FIGS. 10, 15-18, and 20, fabric 14 includes first and second fabric segments 14-1 and 14-2 separated by a gap such as gap G. Each fabric segment 14-1 and 14-2 wraps fully or partially around core 42. Conductive strands 16C may include exposed conductive segments 80 that protrude out from fabric 14 and that terminate in gap G to form electrical connections with component 26. Polymer material 30 may be molded around component 26 and/or fabric segments 14-1 and 14-2 (e.g., as in the examples of FIGS. 10 and 20), or polymer material 30 may form an internal attachment mechanism between component 26 and fabric 14 that is not exposed on the outer surface of fabric 14 (e.g., as in the examples of FIGS. 15 and 16). If desired, fabric 14 may be covered and/or wrapped in one or more cover layers such as cover layer 34 of FIG. 5.

FIG. 22 is a cutaway view of item 10 showing how polymer 30 may have interlocking engagement features with fabric 14 and component 26. In the example of FIG. 22, component 26 has one or more recesses such as recesses 118 that receive respective portions of polymer 30. Additionally, fabric 14 may include one or more recesses such as openings 120 that receive respective portions of polymer 30. Polymer 30 may span across gap G. If desired, fabric segments 14-1 and 14-2 may also have portions that span across gap G (e.g., upper and lower flaps that sandwich component 26). Conductive strands 16C may include exposed conductive segments 80 that protrude out from fabric 14 and that terminate in gap G to form electrical connections with component 26. If desired, fabric 14 may be covered and/or wrapped in one or more cover layers such as cover layer 34 of FIG. 5.

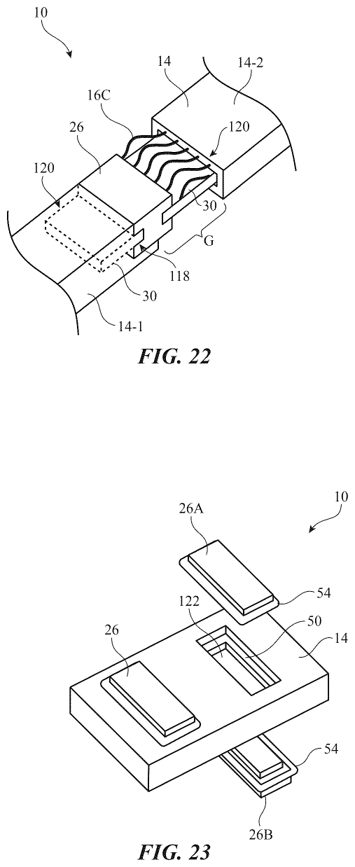

In the example of FIG. 23, fabric 14 includes one or more holes such as openings 122 for receiving electrical components 26. Each opening 122 may be lined with a grommet such as grommet 50. Grommet 50 may be a ring of polymer, metal, or any other suitable material. If desired, component 26 may include edges 54 that mate with grommet 50 in opening 122. A single component 26 may be mounted in each opening 122, or component 26 may include first and second component portions 26A and 26B that are both received in a given opening 122.

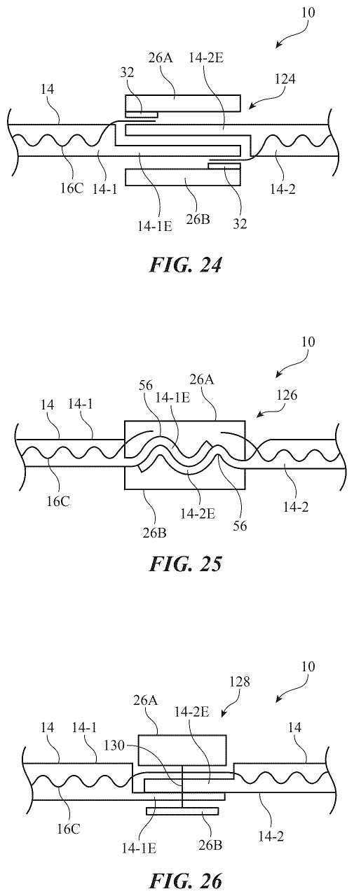

FIGS. 24, 25, and 25 are side views of item 10 showing different joint connections between first and second fabric segments 14-1 and 14-2. In the example of FIG. 24, fabric segments 14-1 and 14-2 have respective ends 14-1E and 14-2E that are coupled at a lap joint such as lap joint 124 in which fabric segment 14-1 is flush with fabric segment 14-2. In this example, ends 14-1E and 14-2E are interposed between first and second component portions 26A and 26B. Conductive strands 16C have ends that terminate at lap joint 124 to form electrical connections with component 26.

In the example of FIG. 25, fabric segments 14-1 and 14-2 have respective ends 14-1E and 14-2E that are coupled at joint 126 and that have interlocking shapes (e.g., interlocking wavy shapes). In this example, ends 14-1E and 14-2E are interposed between first and second component portions 26A and 26B that also have interlocking shapes to match the interlocking shapes of fabric ends 14-1E and 14-2E. Conductive strands 16C have ends that terminate at joint 126 to form electrical connections with component 26.

In the example of FIG. 26, fabric segments 14-1 and 14-2 have respective ends 14-1E and 14-2E that are coupled at joint 128. In this example, ends 14-1E and 14-2E are interposed between first and second component portions 26A and 26B that are connected via a pin or other interconnect such as pin 130. Pin 130 may form a mechanical and/or electrical connection between component portions 26A and 26B. Pin 130 may also serve to attach end 14-1E of fabric segment 14-1 to end 14-2E of fabric segment 14-2. Conductive strands 16C have ends that terminate at joint 128 to form electrical connections with component 26.

The foregoing is merely illustrative and various modifications can be made to the described embodiments. The foregoing embodiments may be implemented individually or in any combination.

What is claimed is:

1. An electronic device, comprising:
first and second fabric segments separated by a gap, wherein the first fabric segment has a first conductive strand that terminates in the gap and the fabric segment has a second conductive strand that terminates in the gap; and
an electrical component mounted in the gap and electrically coupled to the first and second conductive strands.

2. The electronic device defined in claim 1 wherein the first and second fabric segments are non-overlapping with the electrical component.

3. The electronic device defined in claim 1 further comprising a polymer material that attaches the electrical component to the first and second fabric segments.

4. The electronic device defined in claim 3 wherein the polymer material spans the gap between the first and second fabric segments.

5. The electronic device defined in claim 3 wherein the polymer material forms a ring around the electronic component.

6. The electronic device defined in claim 3 wherein the component has a recess and wherein the polymer material is received within the recess.

7. The electronic device defined in claim 1 wherein the first and second fabric segments have respective outer surfaces and wherein the electrical component is flush with the outer surfaces of the first and second fabric segments.

8. The electronic device defined in claim 1 wherein the first conductive strand is one of a first number of conductive strands in the first fabric segment that are coupled to the electrical component, wherein the second conductive strand is one of a second number of conductive strands in the second fabric segment that are coupled to the electrical component, and wherein the first and second numbers are different.

9. The electronic device defined in claim 1 further comprising a third fabric segment separated from the second fabric segment by an additional gap, wherein the third fabric segment has a third conductive strand that terminates in the additional gap, wherein the second conductive strand terminates in the additional gap, the electronic device further comprising an additional electrical component mounted in the additional gap and electrically coupled to the second and third conductive strands.

10. The electronic device defined in claim 1 further comprising a non-woven composite material that is interlaced with the first and second fabric segments and that spans across the gap.

11. The electronic device defined in claim 1 wherein the first and second fabric segments and the electrical component are wrapped around a core.

12. An electronic device, comprising:
fabric having a first region with a first thickness and a second region with a second thickness that is less than the first thickness;
an electrical component mounted in a recess in the second region; and
first and second conductive strands that terminate in the recess and that are electrically coupled to the electrical component.

13. The electronic device defined in claim 12 further comprising a polymer material that attaches the electrical component to the fabric.

14. The electronic device defined in claim 12 wherein the polymer material spans across the recess and captures respective ends of the first and second conductive strands.

15. The electronic device defined in claim 12 wherein the fabric has an outer surface and wherein the electrical component is flush with the outer surface.

16. The electronic device defined in claim 12 further comprising a strain relief layer overlapping the electrical component.

17. The electronic device defined in claim 12 further comprising an additional electrical component mounted in an additional recess in the second region and overlapping the electrical component.

18. An electronic device, comprising:
first and second fabric segments having respective first and second fabric ends that overlap one another at a joint;
an electrical component having first and second portions, wherein the first and second fabric ends are interposed between the first and second portions of the electrical component; and
a conductive strand in the first fabric segment that is electrically coupled to the electrical component.

19. The electronic device defined in claim 18 wherein the conductive strand terminates at the electrical component.

20. The electronic device defined in claim 19 further comprising an additional conductive strand in the second fabric segment, wherein the additional conductive strand terminates at and is electrically coupled to the electrical component.
